(19) United States
(12) Patent Application Publication
(10) Pub. No.: US 2007/0176517 A1
(43) Pub. Date: Aug. 2, 2007

(54) SURFACE MOUNT TYPE CRYSTAL OSCILLATOR

(76) Inventors: Kouichi MORIYA, Sayama-shi (JP); Tsutomu YAMAKAWA, Sayama-shi (JP)

Correspondence Address: KNOBBE MARTENS OLSON & BEAR LLP, 2040 MAIN STREET, FOURTEENTH FLOOR, IRVINE, CA, 92614, US

(21) Appl. No.: 11/668,994

(22) Filed: Jan. 30, 2007

(30) Foreign Application Priority Data
Jan. 31, 2006 (JP) 2006-023955

(51) Int. Cl. H01L 41/053

(52) U.S. Cl. 310/348

(57) ABSTRACT

A surface mount type crystal oscillator is provided with: a container body having a bottom plate layer and a frame wall layer which has an opening, the frame wall layer being laminated on the bottom plate layer wherein a recess of the container body is formed by the opening; a crystal blank housed inside the recess; and an IC chip in which an oscillation circuit that uses the crystal blank is integrated. The IC chip has IC terminals used for external connections on one principal surface of the IC chip and is secured to the bottom plate layer. The IC chip is secured to the bottom plate layer by way of an anisotropic conductive material such that the one principal surface of the IC chip confronts the bottom plate layer.

### BACKGROUND OF THE INVENTION

1. Field of the Invention

The present invention relates to quartz crystal oscillator provided with a quartz crystal blank and an IC (integrated circuit) chip in which an oscillation circuit using the crystal blank is integrated, and more particularly, relates to a surface mount type crystal oscillator that uses a container body having a recess and in which the IC chip is secured within the recess.

2. Description of the Related Art

A surface mount type crystal oscillator in which a crystal blank and an IC chip in which an oscillation circuit is integrated that uses the crystal blank are accommodated within a container for surface mounting is both light and compact and is therefore incorporated in various types of portable electronic devices as a reference source for frequency and time. One representative example of a surface mount type crystal oscillator employs a container body composed of laminated ceramics and having a recess, the IC chip being secured within the recess by means of ultrasonic thermo-compression bonding that uses bumps, and the crystal blank also being accommodated within the recess. Further, representative examples of crystal oscillators that employ container bodies having recesses include: a single-chamber construction in which a single recess is provided in the container body, the crystal blank and IC chip being accommodated within the recess; and an H-type construction that employs a container body in which recesses are provided on both principal surfaces of the container body to produce an H-shaped profile wherein the crystal blank is accommodated within one recess and the IC chip is accommodated in the other recess.

FIG. 1 shows a surface mount type crystal oscillator of the single-chamber construction of the prior art. The crystal oscillator shown in the figure is a component in which IC chip 2 and crystal blank 3 are accommodated within container body 1 to produce a single unit. Container body 1 is composed of laminated ceramics in which substantially rectangular and planar bottom plate layer 1a is laminated with frame wall layers 1b each having a substantially rectangular opening. A recess for accommodating IC chip 2 and crystal blank 3 is formed by the openings formed in frame wall layers 1b. In this case, frame wall layers 1b are realized by laminating upper layer 1b1 and lower layer 1b2, and the opening provided in upper layer 1b1 is larger than the opening in lower layer 1b2 to form a stepped portion in the inner wall of the recess on at least one side of the recess of container body 1. A pair of holding terminals 12 used for retaining crystal blank 2 is provided on the upper surface of the stepped portion.

Mounting terminals 9 used when surface mounting this crystal oscillator on a wiring board are provided in the four corners of the outside bottom surface of container body 1. These mounting terminals 9 include, for example, a power supply terminal, a grounding terminal, and an output terminal for oscillation output.

As shown in FIG. 2, IC chip 2 is a component in which electronic circuits including the oscillation circuit that uses crystal blank 3 are integrated on a semiconductor substrate. The oscillation circuit is formed on one principal surface of the semiconductor substrate by an ordinary semiconductor device fabrication process. Of the two principal surfaces of IC chip 2, the surface on which the oscillation circuit is formed on the semiconductor substrate is referred to as the “circuit formation surface.” A plurality of IC terminals 4 for connecting IC chip 2 to external circuits is also formed on the circuit formation surface. IC terminals 4 include, for example, a power supply terminal, a grounding terminal, an oscillation output terminal, and a pair of connection terminals for connecting to the crystal blank.

As shown in FIG. 1, circuit terminals 6 which correspond to IC terminals 4 are provided on the inner bottom surface of the recess of container body 1. Circuit terminals 6 that correspond to the power supply terminal, grounding terminal, and oscillation output terminal of IC chip 2 are electrically connected to mounting terminals 9 by way of conductive paths formed on the laminated plane between bottom plate layer 1a and frame wall layer 1b. Circuit terminals 6 that correspond to the pair of connection terminals of IC chip 2 are electrically connected to the pair of holding terminals 12 by way of conductive paths formed on the inner wall of the recess. IC chip 2 is secured to the inner bottom surface of the recess of receptacle 1 such that the circuit formation surface confronts the bottom surface of the recess by electrically and mechanically connecting IC terminals 4 to circuit terminals 6 by means of ultrasonic thermo-compression bonding that uses bumps 7. In ultrasonic thermo-compression bonding, IC terminals 4 are positioned on circuit terminals 6 with bumps 7 placed on IC terminals 4, vibration produced by ultrasonic waves is applied to IC chip 2 while applying pressure from the principal surface of IC chip 2 that is not the circuit formation surface, and bumps 7 are thus bonded to both IC terminals 4 and circuit terminals 6.

As shown in FIG. 3, crystal blank 3 comprises, for example, a substantially rectangular AT-cut quartz crystal blank wherein excitation electrodes 5a are provided on both principal surfaces and extension electrodes 5b extend from these excitation electrodes 5a toward both sides of one end of crystal blank 3. Both sides of the one end of crystal blank 3 to which extension electrodes 5b extend are secured by, for example, thermosetting conductive adhesive 8 to above-described holding terminals 12, whereby crystal blank 3 is electrically and mechanically connected to holding terminals 12 and crystal blank 3 is held within the recess. Since crystal blank 3 is electrically connected to holding terminals, crystal blank 3 is electrically connected to the oscillation circuit within IC chip 2 by way of holding terminals 12, the conductive paths, and circuit terminals 6.

Metal ring 17 for welding is provided on the upper surface of upper layer 1b2 of frame wall layer 1b to surround the recess, and by bonding metal cover 10 to this metal ring 17 by means of, for example, seam welding, the opening face of the recess that houses crystal blank 3 is closed to hermetically seal crystal blank 3 within this recess.

FIG. 4 shows a surface mount type crystal oscillator of the H-shaped construction of the prior art. The crystal oscillator of the H-shaped construction is similar to the crystal oscillator of the single-chamber construction shown in FIG. 1 in that IC chip 2 and crystal blank 3 are accommodated in container body 1, but differs from the construction shown in FIG. 1 in that recesses are provided in both of the two principal surfaces of container body 1, IC chip 2 being housed in one recess, and crystal blank 3 being housed in the other recess. The following explanation regards the crystal oscillator shown in FIG. 4 and focuses on the points of difference with the crystal oscillator shown in FIG.

Container body 1 is composed of laminated ceramics including a substantially rectangular and planar bottom plate layer 1a and frame wall layers 1b, 1c that are laminated on respective principal surfaces of bottom plate layer 1a, a substantially rectangular opening being formed in each of frame wall layers 1b, 1c. Recess 20a for accommodating crystal blank 3 is formed by the opening of frame wall layer 1b, and recess 20b for accommodating IC chip 2 is formed by the opening of frame wall layer 1c. The pair of holding terminals 12 are provided on the bottom surface of recess 20a, and crystal blank 3 is secured to holding terminals 12 by thermosetting conductive adhesive 8. Metal ring 17 is provided on the upper surface of frame wall layer 1b as previously described, and crystal blank 3 is hermetically sealed inside recess 20a by bonding metal cover 10 to metal ring 17.

Circuit terminals 6 are provided on the bottom surface of recess 20b, and IC chip 2 is secured to the bottom surface of recess 20b by bonding IC terminals 4 of IC chip 2 to circuit terminals 6 by means of ultrasonic thermo-compression bonding that uses bumps 7. Circuit terminals 6 that correspond to the connection terminals of IC chip 2 are electrically connected to holding terminals 12 by way of via-holes 11 provided in bottom plate layer 1a. Mounting terminals 9 are formed in the four corners on the surface of frame wall layer 1c. In this crystal oscillator, IC chip 2 is not hermetically sealed inside recess 20b, and protective resin 21 is therefore injected as “underfill” into recess 20b to protect the circuit formation surface of IC chip 2.

In the above-described surface mount type crystal oscillator of the prior art, regardless of whether the single-chamber construction or the H-shaped construction is employed, IC chip 2 is secured to bottom plate layer 1a by ultrasonic thermo-compression bonding, and both constructions therefore necessitate the use of expensive ultrasonic thermo-compression bonding equipment, increasing the cost of plant and equipment investment. In addition, ultrasonic thermo-compression bonding that uses bumps 7 requires that bottom plate layer 1a be flat. If the degree of flatness of bottom plate layer 1a falls below the range of permissible accuracy, the electrical connections between IC chip 2 and circuit terminals 6 becomes defective, and this is a fatal flaw for a crystal oscillator. Crystal oscillators in which IC chips are secured to container bodies by means of ultrasonic thermo-compression bonding that uses bumps therefore suffer from the problem of low productivity.

In a surface mount type crystal oscillator of the single-chamber construction, the degree of flatness of bottom plate layer 1a is comparatively good and the fabrication costs of container body 1 are low, but the need to provide a steppe portion in the inner walls of the recess for securing the two sides of one end of crystal blank 3 complicates reduction of the size of the planar outer shape of container body 1. In a surface mount type crystal oscillator of the H-shaped construction, on the other hand, the size of the planar outer shape of container body 1 can be reduced because there is no need to provide a stepped potion in the inner walls of the recesses, but this construction suffers from the problems that the costs of fabricating container body 1 are high, and moreover, bottom plate layer 1a hangs unsecured between frame wall layers 1b and 1c, and bottom plate layer 1a is therefore difficult to keep level, complicating the ultrasonic thermo-compression bonding of IC chip 2.

Japanese Patent Laid-Open Application No. 2004-128528 (JP-A-2004-128528) discloses a surface mount type crystal oscillator that uses a container body having only one recess wherein a crystal blank is hermetically sealed within the container body and an IC chip is secured to the outer walls of the container body.

### SUMMARY OF THE INVENTION

It is an object of the present invention to provide a surface mount type crystal oscillator that can both achieve a more compact structure and improve productivity by enabling reliable electrical connection of an IC chip to the container body without using ultrasonic thermo-compression bonding.

The object of the present invention is achieved by a surface mount type crystal oscillator that is provided with: a container body having a bottom plate layer and a frame wall layer which has an opening, the frame wall layer being laminated on the bottom plate layer, wherein a recess of the container body is formed by said opening; a crystal blank housed inside the recess; and an IC chip in which an oscillation circuit that uses the crystal blank is integrated, the IC chip having IC terminals used for external connections on one principal surface of the IC chip; wherein the IC chip is secured to the bottom plate layer by way of an anisotropic conductive material such that the one principal surface of the IC chip confronts the bottom plate layer.

When fabricating the crystal oscillator of this configuration, the IC chip may be secured by thermo-compression bonding onto anisotropic conductive material that is provisionally fixed to the bottom plate layer, whereby the expensive equipment for ultrasonic thermo-compression bonding is not required. In addition, even when the bottom plate layer has a poor degree of flatness, the flexibility of the anisotropic conductive material can accommodate the effect of this unevenness. As a result, reliable electrical connections can be realized between the bottom plate layer and the IC chip, and this ability enables an increase in the productivity of the surface mount type crystal oscillator.

Examples of materials that can be employed preferentially as the anisotropic conductive material include an anisotropic conductive sheet, or an anisotropic conductive adhesive.

### BRIEF DESCRIPTION OF THE DRAWINGS

FIG. 1 is a sectional view showing the configuration of a surface mount type crystal oscillator of the single-chamber construction of the prior art;

FIG. 2 is a plan view showing an IC chip;

FIG. 3 is a plan view showing a crystal blank;

FIG. 4 is a sectional view showing the configuration of a surface mount type crystal oscillator of the H-shaped construction of the prior art;

FIGS. 5A and 5B are a sectional view and a bottom plan view, respectively, showing the configuration of a surface mount type crystal oscillator according to an embodiment of the present invention;

FIG. 5C is an enlarged view of the dotted-line box labeled “P” in FIG. 5A;

FIG. 6A is a sectional view showing the configuration of a surface mount type crystal oscillator of the single-chamber construction according to another embodiment of the present invention; and

FIG. 6B is a sectional view showing the configuration of a surface mount type crystal oscillator of the H-shaped construction based on the present invention.

### DETAILED DESCRIPTION OF THE PREFERRED EMBODIMENTS

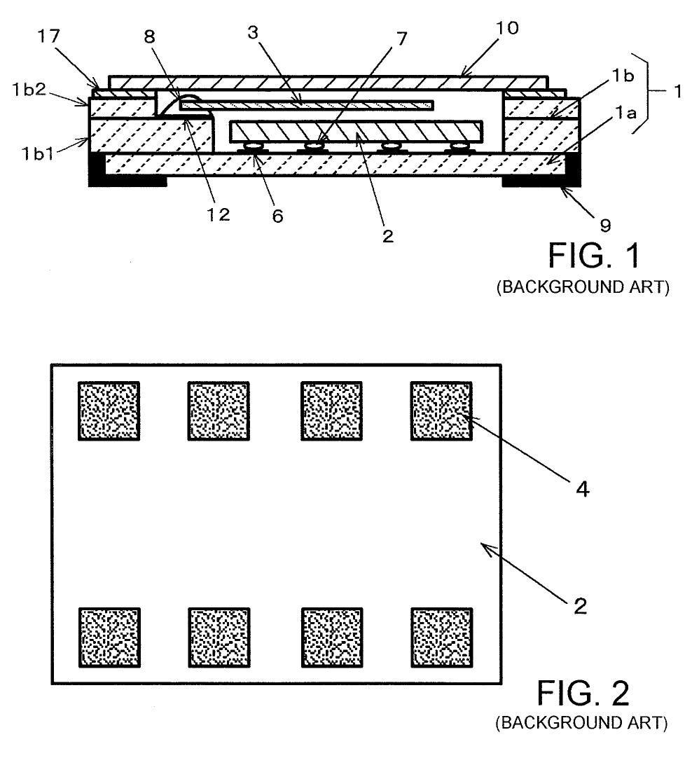

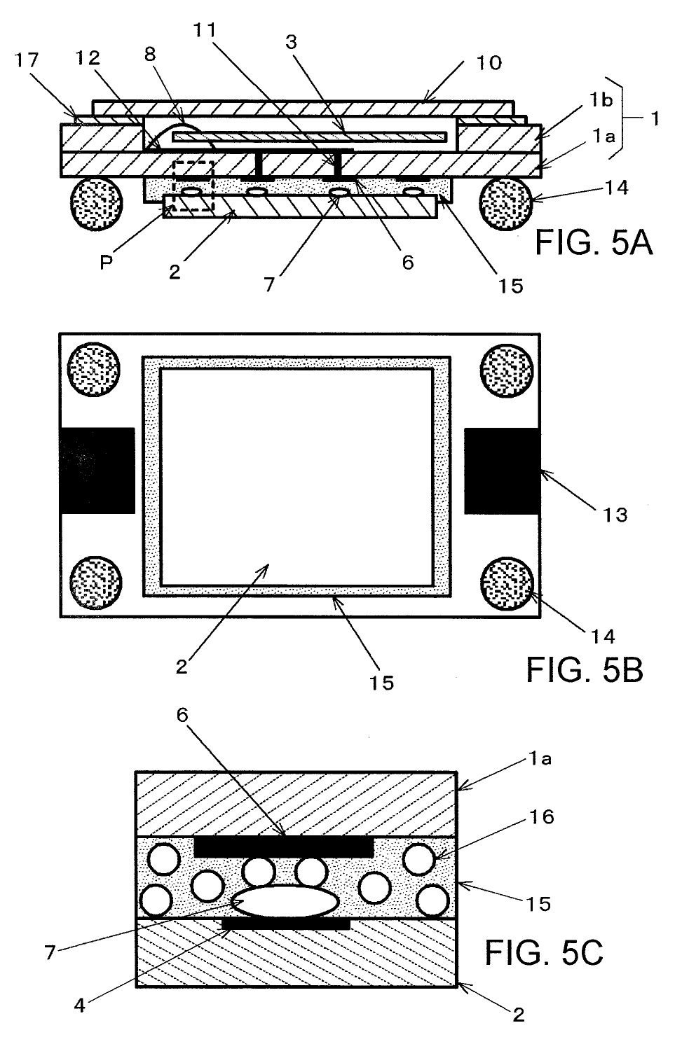

In FIGS. 5A to 5C showing the surface mount type crystal oscillator according to an embodiment of the present invention, constituent elements identical to those of FIGS. 1 to 4 are given the same reference numerals, and redundant explanation of these elements is not repeated.

The surface mount type crystal oscillator shown in FIGS. 5A to 5C is of a configuration in which IC chip 2 and crystal blank 3 are formed as a single unit with container body 1 composed of laminated ceramics, as previously explained. As IC chip 2, a component is used that is similar to the IC chip described using FIG. 2.

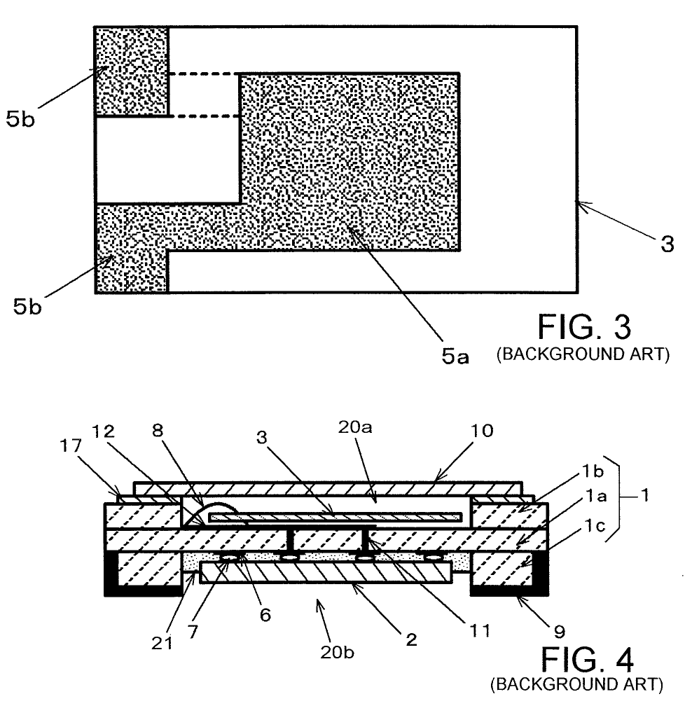

Container body 1 is provided with a substantially rectangular bottom plate layer 1a and a frame wall layer 1b having a substantially rectangular opening and laminated on one principal surface of bottom plate layer 1a, the recess for housing crystal blank 3 being formed by the opening in frame wall layer 1b. A stepped portion is not formed in the inner wall of this recess. A pair of holding terminals 12 are provided on the bottom surface of the recess. Crystal blank 3 is similar to the crystal blank shown using FIG. 3, and both sides of one end of this crystal blank 3 to which extension electrodes 5b extend are secured to holding terminals 12 by conductive adhesive 8. Metal ring 17 is provided on the upper surface of frame wall layer 1b that surrounds the recess, and crystal blank 3 is hermetically sealed inside the recess by bonding metal cover 10 to this metal ring 17 by means of seam welding.

Circuit terminals 6 are provided on the outside bottom surface of container body 1, i.e., the principal surface of bottom plate layer 1a that is not on the side of the recess. These circuit terminals 6 correspond to IC terminals 4 of IC chip 2 as with the previously described crystal oscillator. Of circuit terminals 6, the two circuit terminals that correspond to the pair of connection terminals of IC chip 2 pass by way of via-holes 11 provided in bottom plate layer 1a and electrically connect to the pair of holding terminals 12. Crystal inspection terminals 13 that are electrically connected to holding terminals 12 by way of conductive paths (not shown) are provided in the central portions on the pair of opposite sides of the outside bottom surface of container body 1. Crystal inspection terminals 13 are used for measuring the oscillation characteristics of crystal blank 3 as a crystal element by, for example, placing probes (not shown) in contact with these crystal inspection terminals after crystal blank 3 has been housed inside the recess.

Further, metal balls 14 composed of, for example, solder, are secured to each of the four corners of the outside bottom surface of container body 1. Metal balls 14 correspond to the mounting terminals in the above-described surface mount type crystal oscillator of the prior art, and are used when surface mounting this crystal oscillator of the present embodiment on a wiring board. The four metal balls 14 shown in the figure are electrically connected by way of conductive paths (not shown) to circuit terminals 6 that correspond to, for example, the power supply terminal, grounding terminal, and output terminal of IC chip 2.

IC chip 2 is secured to the outside bottom surface of container body 1 by way of anisotropic conductive sheet 15 also referred to as “ACF (Anisotropic Conductive Film)” such that the circuit formation surface on which IC terminals 4 of IC chip 2 are exposed confronts bottom plate layer 1a, i.e., the outside bottom surface of container body 1. Anisotropic conductive sheet 15 is a flexible sheet composed of a polymer material that contains metal granules 16, and may be a component having anisotropy in electrical conductivity. Here, the planar outer size of anisotropic conductive sheet 15 is greater than the planar outer size of IC chip 2.

Explanation here regards the process of securing IC chip 2 to the outside bottom surface of container body 1 using anisotropic conductive sheet 15.

Anisotropic conductive sheet 15 is first provisionally fixed at a prescribed position on the outside bottom surface of container body 1 by a preparatory application of heat. Bumps 7 are secured to each of IC terminals 4 on IC chip 2. The circuit formation surface of IC chip 2 is next bonded onto anisotropic conductive sheet 15 by means of thermo-compression. Thermo-compression bonding is carried out by, for example, using an implement (not shown) that incorporates a heater to apply both heat and pressure to the principal surface of IC chip 2 that is not the circuit formation surface. IC chip 2 is thus secured to the outside bottom surface of container body 1 with anisotropic conductive sheet 15 interposed therebetween. As shown in FIG. 5C, under the pressure in the perpendicular direction at this time, metal granules 16 in anisotropic conductive sheet 15 electrically connect bumps 7 and circuit terminals 6, and IC chip 2 is thus secured to the outside bottom surface of container body 1 with this electrical connection maintained unchanged after the thermo-compression is terminated.

Surface mount type crystal oscillator of the present embodiment thus enables thermo-compression bonding of IC chip 2 to container body 1 by means of simple equipment such as a hot plate without necessitating the expensive equipment for ultrasonic thermo-compression bonding. In addition, even when the degree of flatness of the outside bottom surface of container body 1, i.e., of bottom plate layer 1a, deviates from the permissible value in the crystal oscillator of the prior art, the adverse effect of this unevenness can be absorbed by the flexibility of anisotropic conductive sheet 15, and a reliable electrical connection can therefore be realized between IC terminals 4 and circuit terminals 6. The present embodiment can therefore improve the productivity of a crystal oscillator. In addition, because the need for providing a stepped portion in the inner wall of the recess is eliminated, the present embodiment allows a reduction of the planar outer size of the crystal oscillator.

During thermo-compression bonding, bumps 7 of IC chip 2 are buried in anisotropic conductive sheet 15 and the circuit formation surface of IC chip 2 contacts anisotropic conductive sheet 15. The circuit formation surface of IC chip 2 is thus protected by anisotropic conductive sheet 15 and there is consequently no need to provide the protective resin layer that was provided as underfill in the crystal oscillator of the prior art shown in FIG. 4. In particular, in the case of the present embodiment, the surface to which IC chip 2 is secured on the container body is flat, and as a result, even if a protective resin in liquid form were injected onto this surface, the protective resin would only flow off, making the formation of a protective resin layer (i.e., underfill) problematic. For this reason as well, the use of anisotropic conductive sheet 15 is effective.

In this embodiment, the outside bottom surface of the container body is flat despite the inclusion of metal balls 14 on its four corners, and this flatness can facilitate the provisional fixing of anisotropic conductive sheet 15 and the task of thermo-compression bonding of IC chip 2, and further, can facilitate the measurement of oscillation characteristics that is carried out by placing probes in contact with crystal inspection terminals 13. In cases in which metal balls 14 hinder operations, metal balls 14 may be provided on the four corners of the outside bottom surface after the operation of thermo-compression bonding of IC chip 2.

In the surface mount type crystal oscillator of the present embodiment, metal balls 14 have the same functions as metal balls in a BGA (Ball Grid Array) IC package. Accordingly, this crystal oscillator is mounted on a wiring board by: positioning this crystal oscillator such that metal balls 14 contact a prescribed circuit pattern on the wiring board, melting the metal balls in a heating furnace, and then cooling.

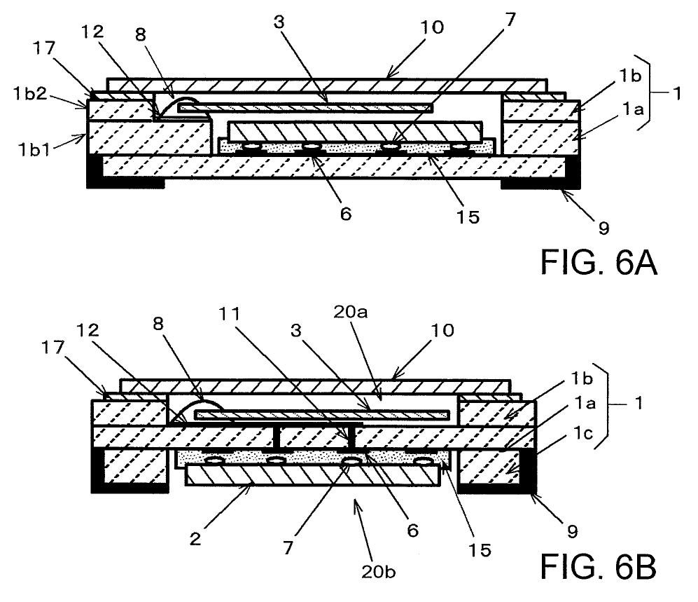

A configuration in which IC chip 2 is secured to container body 1 using an anisotropic conductive sheet instead of implementing ultrasonic thermo-compression bonding can be used in the surface mount type crystal oscillators of the prior art shown in FIGS. 1 and 4. FIG. 6A shows a configuration in which IC chip 2 is secured to the bottom surface of the recess by way of anisotropic conductive sheet 15 in the crystal oscillator shown in FIG. 1, and FIG. 6B shows a configuration in which IC chip 2 is secured to the bottom surface of recess 20b by way of anisotropic conductive sheet 15 in the crystal oscillator shown in FIG. 4. In either of the cases shown in FIGS. 6A and 6B, the process of implementing thermo-compression to bond IC chip 2 by way of anisotropic conductive sheet 15 is similar to the case described above. These cases similarly do not call for the expensive equipment for ultrasonic thermo-compression bonding, and further, enable the realization of reliable electrical connections through the absorption of unevenness by anisotropic conductive sheet 15 when the degree of flatness of bottom plate layer 1a of container body 1 is poor, and enable an increase in the productivity of surface mount type crystal oscillators.

In the foregoing explanation, a case was described in which bumps 7 are provided on each IC terminal 4 and thermo-compression bonding is realized by way of anisotropic conductive sheet 15, but a configuration is also possible in which bumps are not provided and IC terminals 4 and circuit terminals 6 are bonded directly by thermo-compression by way of anisotropic conductive sheet 15. Although an example was described in which anisotropic conductive sheet 15 was used as the anisotropic conductive material, an anisotropic conductive adhesive may also be used in place of anisotropic conductive sheet 15.

What is claimed is:

1. A surface mount type crystal oscillator comprising:
a container body having a bottom plate layer and a frame wall layer which has an opening, said frame wall layer being laminated on said bottom plate layer, wherein a recess of said container body is formed by said opening;
a crystal blank housed inside said recess; and
an IC chip in which an oscillation circuit that uses said crystal blank is integrated, said IC chip having IC terminals used for external connections on one principal surface of said IC chip;
wherein said IC chip is secured to said bottom plate layer by way of an anisotropic conductive material such that said one principal surface of said IC chip confronts said bottom plate layer.

2. The crystal oscillator according to claim 1, wherein circuit terminals are provided on said bottom plate layer corresponding to positions of said IC terminals, and said anisotropic conductive material electrically connects mutually corresponding IC terminals and circuit terminals.

3. The crystal oscillator according to claim 1, wherein:
said frame wall layer is provided on only one principal surface of said bottom plate layer;
said IC chip is secured to an outside bottom surface of said container body at a position that corresponds to said recess with said anisotropic conductive material being interposed;
an outer periphery of said crystal blank to which extension electrodes of the crystal blank extend is secured to an inner bottom surface of said recess; and
metal balls for mounting are provided in four corners of the outside bottom surface of said container body.

4. The crystal oscillator according to claim 1, wherein:
said frame wall layer is provided on only one principal surface of said bottom plate layer;
said IC chip is secured to an outside bottom surface of said container body at a position that corresponds to said recess with said anisotropic conductive material interposed;
an outer periphery of said crystal blank to which extension electrodes of said crystal blank extend is secured to a stepped portion formed in an inner wall of said recess; and
mounting terminals are provided in four corners of an outside bottom surface of said container body.

5. The crystal oscillator according to claim 1, wherein:
said bottom plate layer has a first principal surface and a second principal surface, and a pair of said frame wall layers are provided on both said first principal surface and said second principal surface, respectively;
an outer periphery of said crystal blank to which extension electrodes of said crystal blank extend is secured to an inner bottom surface of a first recess which is formed on said first principal surface;
said IC chip is secured to said bottom plate layer by being secured to an inner bottom surface of a second recess, which is formed on said second principal surface, with said anisotropic conductive material interposed; and
mounting terminals are provided in four corners of said frame wall layer on the side of said second principal surface.

6. The crystal oscillator according to claim 1, wherein said anisotropic conductive material is an anisotropic conductive sheet or an anisotropic conductive adhesive.
